(19) United States
(12) Patent Application Publication
(10) Pub. No.: US 2004/0212968 A1
(43) Pub. Date: Oct. 28, 2004

(54) DOUBLE HINGE STRUCTURE

(76) Inventor: Jui-Chiang Lin, Taipei City (TW)

Correspondence Address: NAIPO (NORTH AMERICA INTERNATIONAL PATENT OFFICE), P.O. BOX 506, MERRIFIELD, VA, 22116, US

(21) Appl. No.: 10/709,164

(22) Filed: Apr. 19, 2004

(30) Foreign Application Priority Data
Apr. 22, 2003 (TW) 092206499

(51) Int. Cl. G06F 7/00; G06F 17/30; H05K 5/04; H05K 5/00; H05K 5/06

(52) U.S. Cl. 361/755

(57) ABSTRACT

The present invention provides a double hinge structure utilized in folder-style electronic devices (eg: notebooks, portable DVD players, cellphones). The double hinge structure connects a first unit and a second unit of the folder-style electronic device and is utilized for making the first unit rotate to a position directly on top of the second unit or to a position directly underneath the second unit. The double hinge structure contains a plurality of bolts; at least a plate installed and rotatable on the plurality of bolts; and a plurality of fasteners installed and rotatable on the plurality of bolts.

### BACKGROUND OF INVENTION

1. Field of the Invention

The present invention relates to a double hinge structure utilized for connecting a first unit and a second unit of a folder-style electronic device, and more specifically, to a double hinge structure utilized for making the first unit rotate to a position directly on top of the second unit or to a position directly underneath the second unit.

2. Description of the Prior Art

General folder-style electronic devices, such as note-books, portable DVD players, or cellphones, use hinges to connect the main body of the devices to a corresponding screen. Hence, the devices can be opened or closed in a folding manner. Please refer to FIG. 1. FIG. 1 is a three-dimensional diagram of a hinge used in a folder-style electronic device according to the prior art. Please refer to FIG. 2 and FIG. 3. FIG. 2 is a three-dimensional diagram of a closed folder-style electronic device 9 that uses a hinge according to the prior art. FIG. 3 is a three-dimensional diagram of a side view of a closed folder-style electronic device 9 that uses a hinge according to the prior art. When the folder-style electronic device 9 is folded, the screen 91 is positioned directly on top of the input area 92. When folded, the folder-style electronic device 9 maximizes space savings and is convenient for a user to carry. Please refer to FIG. 4. FIG. 4 is a three-dimensional diagram of an open folder-style electronic device 9 that uses a hinge according to the prior art. When the folder-style electronic device 9 is opened, a user can input instructions or perform operations using the input area 92. The screen 91 displays results for the user to confirm. However, folder-style electronic products according to the prior art can only rotate 180 degrees, i.e. the angle between the screen 91 and the input area 92 can at most be 180 degrees (please refer to FIG. 5 and FIG. 6). As such, this is a limitation when a user is using a folder-style electronic product.

### SUMMARY OF INVENTION

It is therefore an objective of the claimed invention to provide a double hinge structure utilized in folder-style electronic devices (eg: notebooks, portable DVD players, cellphones) to solve the above-mentioned problem. The double hinge structure connects a first unit and a second unit of the folder-style electronic device and is utilized for making the first unit rotate to a first position directly on top of the second unit or to a second position directly underneath the second unit. The double hinge structure comprises a plurality of bolts; at least a plate installed and rotatable on the plurality of bolts; and a plurality of fasteners installed and rotatable on the plurality of bolts.

These and other objectives of the claimed invention will no doubt become obvious to those of ordinary skill in the art after reading the following detailed description of the preferred embodiment, which is illustrated in the various figures and drawings.

### BRIEF DESCRIPTION OF DRAWINGS

FIG. 1 is a three-dimensional diagram of a hinge used in a folder-style electronic device according to the prior art.

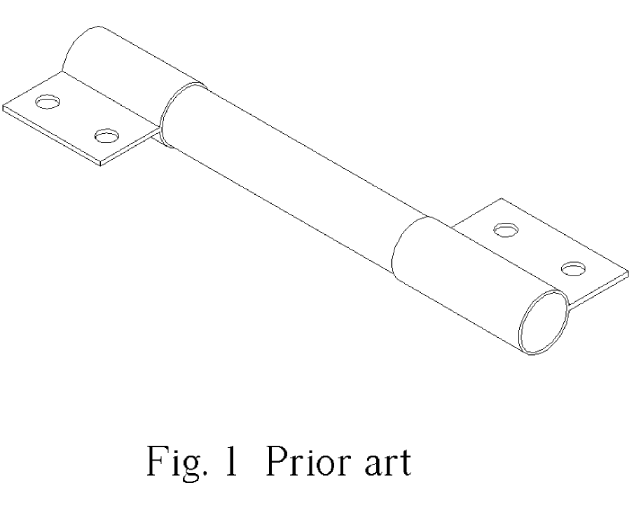

FIG. 2 is a three-dimensional diagram of a closed folder-style electronic device that uses a hinge according to the prior art.

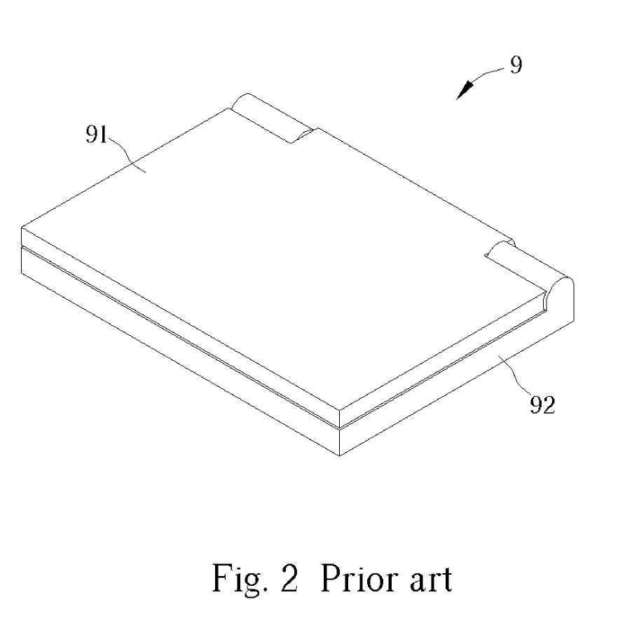

FIG. 3 is a three-dimensional diagram of a side view of a closed folder-style electronic device that uses a hinge according to the prior art.

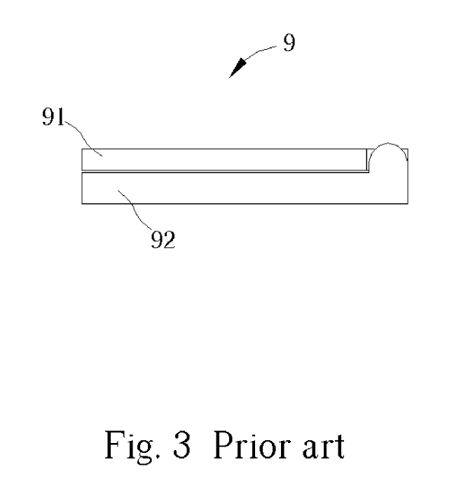

FIG. 4 is a three-dimensional diagram of an open folder-style electronic device that uses a hinge according to the prior art.

FIG. 5 is a three-dimensional diagram of an open folder-style electronic device that uses a hinge according to the prior art when the angle between the input area and the screen is 180 degrees.

FIG. 6 is a three-dimensional diagram of a side view of an open folder-style electronic device that uses a hinge according to the prior art when the angle between the input area and the screen is 180 degrees.

FIG. 7 is a three-dimensional diagram of a double hinge structure according to the present invention.

FIG. 8 is a diagram of a plane view and a side view of the fastener locations and the housing of the double hinge structure.

FIG. 9 is a diagram of a side view of a screen directly on top of an input area.

FIG. 10 is a diagram of a side view of an open folder-style electronic device after the screen is rotated 180 degrees from the position directly on top of the input area where the screen is above the input area.

FIG. 11 is another diagram of a side view of an open folder-style electronic device after the screen is rotated 180 degrees from the position directly on top of the input area where the screen is below the input area.

FIG. 12 is a diagram of a side view of an open folder-style electronic device when the screen is rotated to a position directly underneath the input area and the angle between the input area and the screen is substantially 360 degrees.

FIG. 13 is a three-dimensional diagram of a folder-style electronic device that uses the double hinge structure of FIG. 7.

FIG. 14 is a three-dimensional diagram of another type of double hinge structure according to the present invention.

FIG. 15 is a three-dimensional diagram of a folder-style electronic device that uses the double hinge structure of FIG. 14.

FIG. 16 is a three-dimensional diagram of another type of double hinge structure according to the present invention.

FIG. 17 is a three-dimensional diagram of a folder-style electronic device that uses the double hinge structure of FIG. 16.

FIG. 18 is a three-dimensional diagram of a folder-style electronic device that uses a double hinge structure viewed from a first view.

FIG. 19 is a three-dimensional diagram of a folder-style electronic device that uses a double hinge structure viewed from a second view.

FIG. 20 is a three-dimensional diagram of a folder-style electronic device that uses a double hinge structure viewed from a third view.

FIG. 21 is a three-dimensional diagram of a folder-style electronic device that uses a double hinge structure viewed from a fourth view.

### DETAILED DESCRIPTION

The following embodiments according to the present invention relate to a portable DVD player. However, the present invention can be used in all kinds of folder-style electronic devices, such as notebooks, folder-style digital cameras or cellphones.

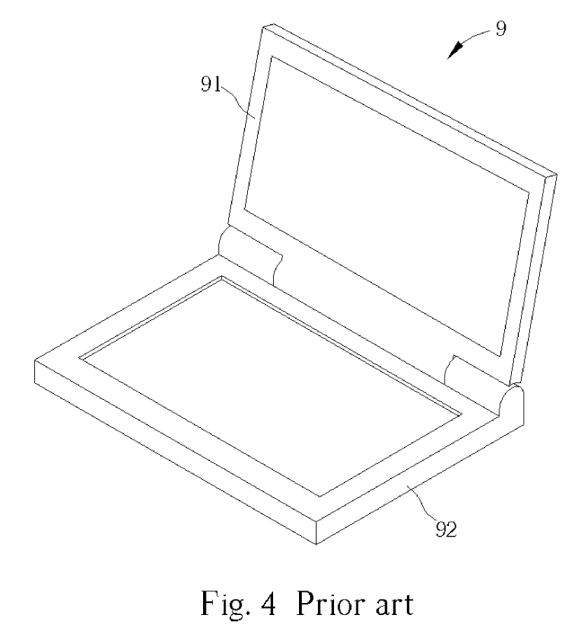

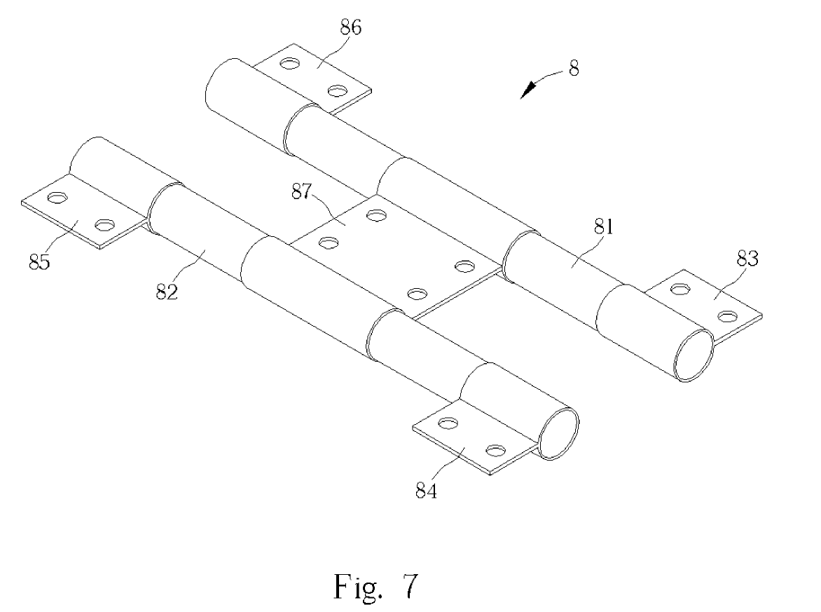

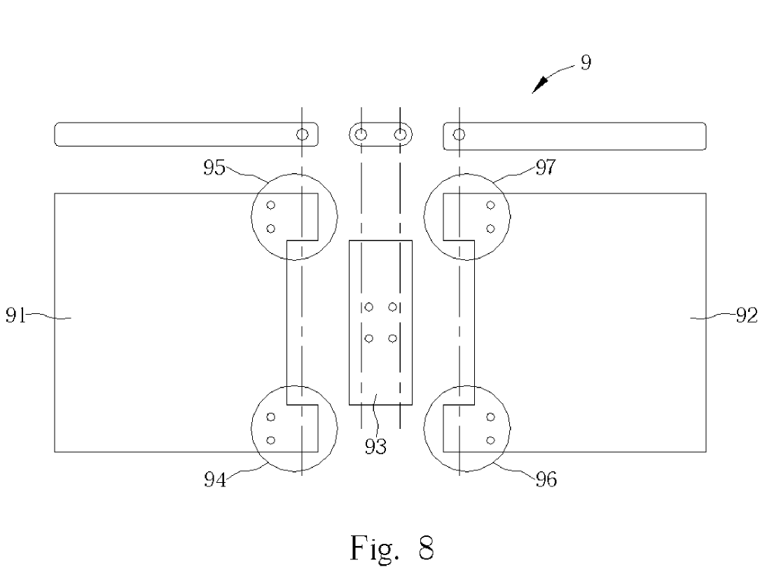

Please refer to FIG. 4. FIG. 4 is a three-dimensional diagram of an open folder-style electronic device 9 that uses a hinge according to the prior art. The folder-style electronic device 9 comprises a screen 91 and an input area 92. A user can input instructions or perform operations through the input area 92. The screen 91 displays results for the users to confirm. Please refer to FIG. 7. FIG. 7 is a three-dimensional diagram of a double hinge structure 8 according to the present invention. The double hinge structure 8 comprises bolts 81 and 82; fasteners 83, 84, 85 and 86; and a plate 87. The fasteners 83, 84, 85, 86 and the plate 87 are installed and rotatable on the bolts 81 and 82. When using different types of double hinge structures, the number of the fasteners and plates can be varied for different double hinge structures. Please refer to FIG. 8. FIG. 8 is a diagram of a plane view and a side view of the fastener locations 95, 97, 96, 94 and the housing of the double hinge structure 93. The fasteners 83, 84, 85, 86 are attached to the corresponding fastener locations 95, 97, 96, 94 of the screen 91 and the input area 92 respectively. Hence, the screen 91 is connected to the input area 92. The plate 87 is attached to the corresponding housing of the double hinge structure 93.

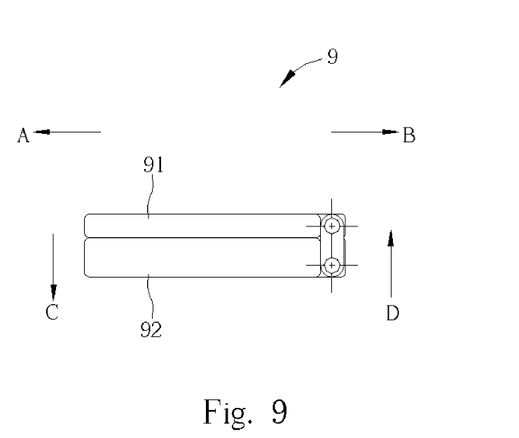

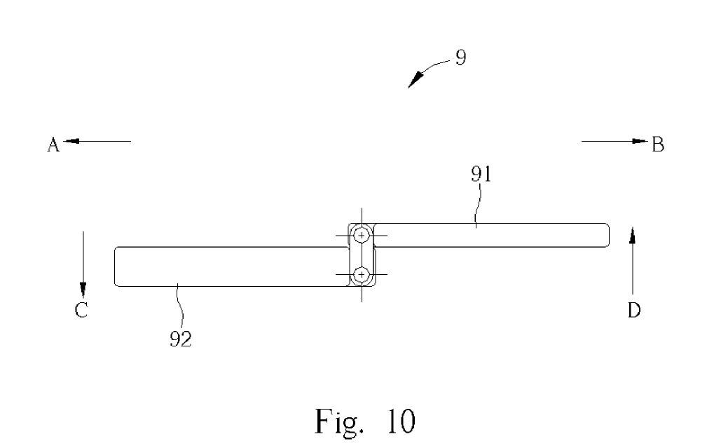

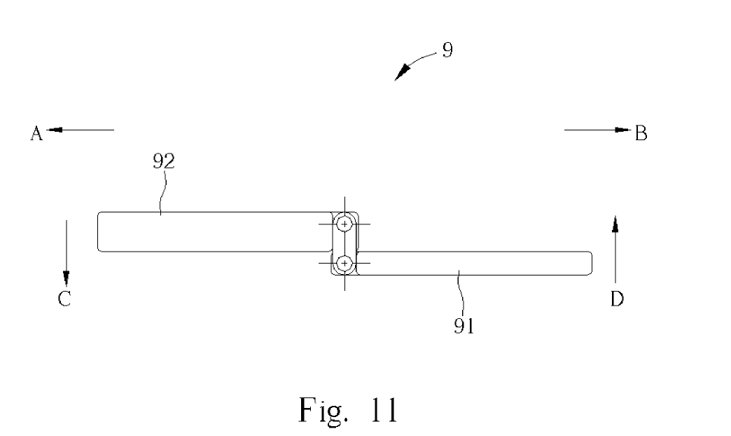

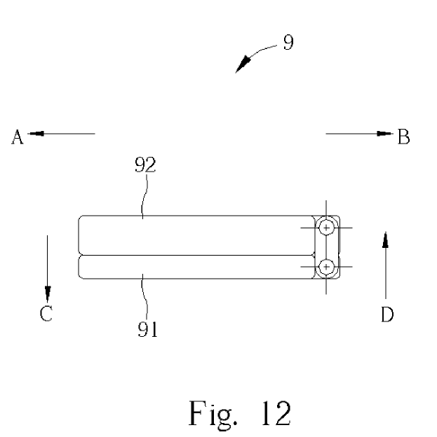

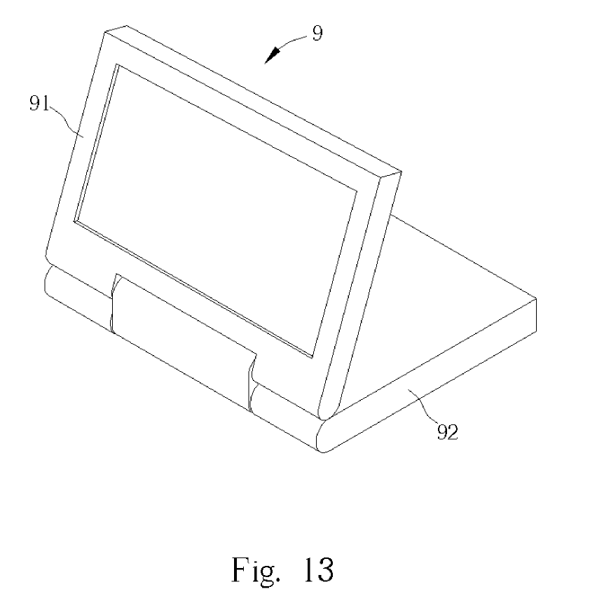

Please refer to FIG. 9. FIG. 9 is a diagram of a side view of a screen on top of an input area 92. When the screen 91 is connected to the input area 92 using the double hinge structure 8 in the above-mentioned description, because of the functioning of the double hinge structure 8, the screen 91 faces downward (direction C) with respect to the input area 92. In this position, the folder-style electronic device 9 is folded, and the screen 91 is directly on top of the input area 92. The fasteners 83, 84, 85, 86 are parallel and toward the left (direction A), and the fasteners 83 and 86 are directly above the fasteners 84 and 85. Please refer to FIG. 10. FIG. 10 is a diagram of a side view of an open folder-style electronic device 9 after the screen 91 is rotated 180 degrees from the position directly on top of the input area 92 where the screen 91 is above the input area 92. After the screen 91 is rotated 180 degrees from the position on top of the input area 92, the screen 91 faces upward (direction D), and is on the right side of the input area 92 (direction B) and above the input area 92. The fasteners 83, 86 are toward the right (direction B), and the fasteners 84, 85 are toward the left (direction A). The fasteners 83, 86 are above the fasteners 84, 85. Please refer to FIG. 11. FIG. 11 is another diagram of a side view of an open folder-style electronic device 9 after the screen 91 is rotated 180 degrees from the position directly on top of the input area 92 where the screen 91 is below the input area 92. Now the screen 91 faces upward (direction D), and is on the right side of the input area 92 (direction B) and below the input area 92. The fasteners 83, 86 are toward the right (direction B), and the fasteners 84, 85 are toward the left (direction A). The fasteners 83, 86 are below the fasteners 84, 85. Please refer to FIG. 12. FIG. 12 is a diagram of a side view of an open folder-style electronic device 9 when the screen 91 is rotated to the position directly underneath the input area 92 and the angle between the input area 92 and the screen 91 is substantially 360 degrees. In this position, the folder-style electronic device 9 is folded, and the screen 91 is facing downward (direction C) and is positioned directly underneath the input area 92. The fasteners 83, 84, 85, 86 are parallel and toward the left (direction A), and the fasteners 83 and 86 are below the fasteners 84 and 85. The screen 91 has been rotated 360 degrees. Please refer to FIG. 13. FIG. 13 is a three-dimensional diagram of a folder-style electronic device 9 that uses a double hinge structure of FIG. 7.

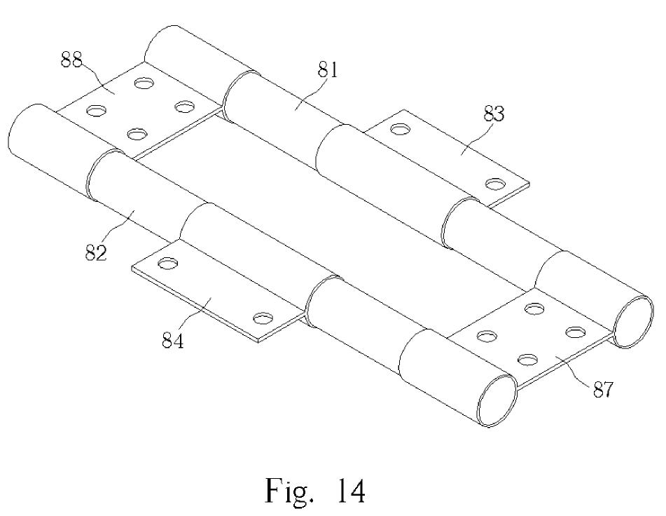

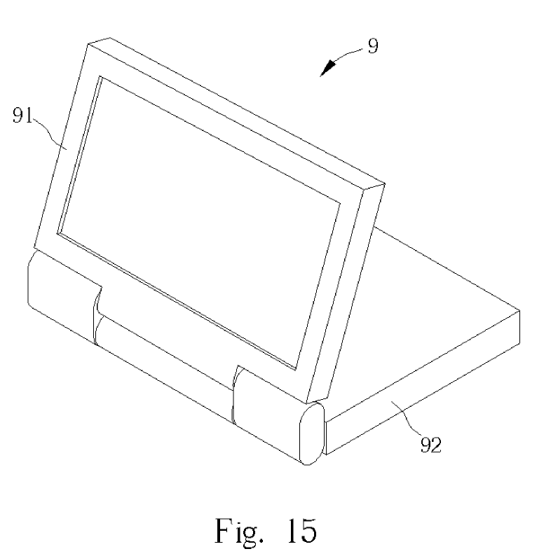

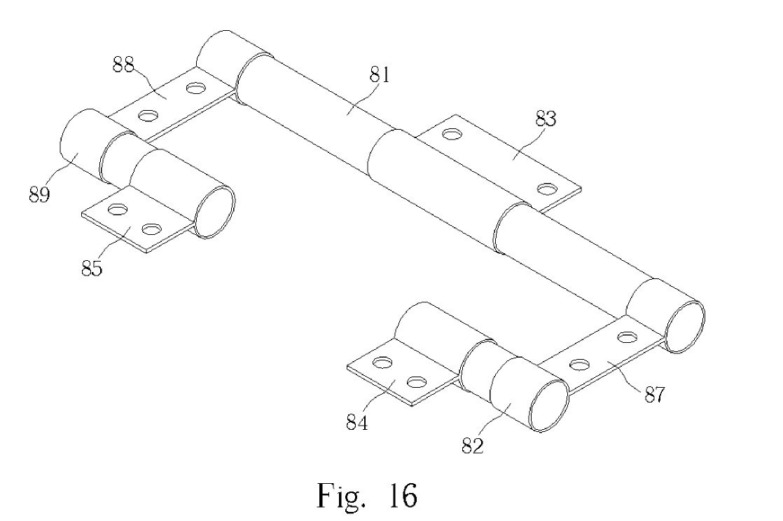

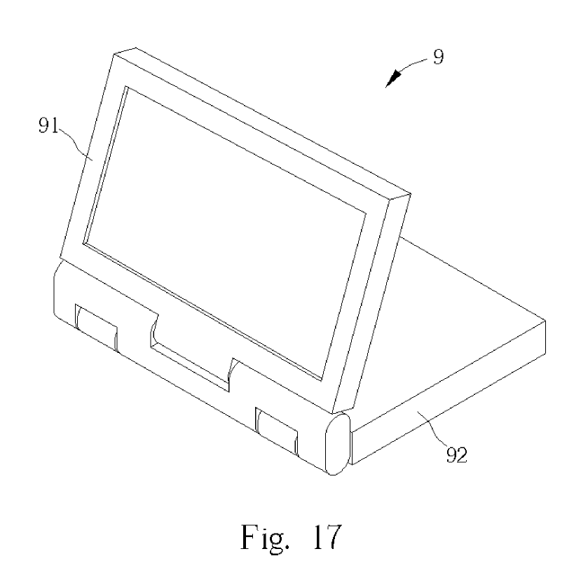

Please refer to FIG. 14, FIG. 15, FIG. 16 and FIG. 17. FIG. 14 is a three-dimensional diagram of another type of double hinge structure according to the present invention. FIG. 15 is a three-dimensional diagram of a folder-style electronic device 9 that uses the double hinge structure of FIG. 14. FIG. 16 is a three-dimensional diagram of another type of double hinge structure according to the present invention. FIG. 17 is a three-dimensional diagram of a folder-style electronic device 9 that uses the double hinge structure of FIG. 16.

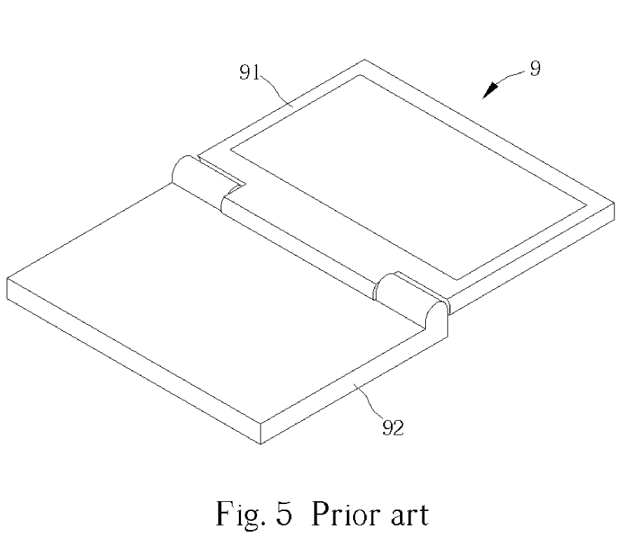

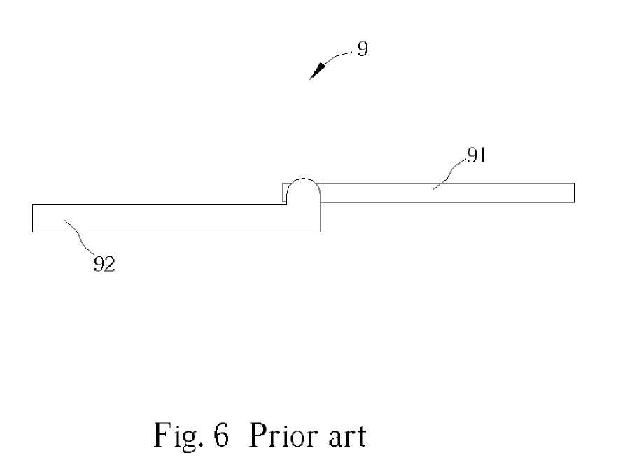

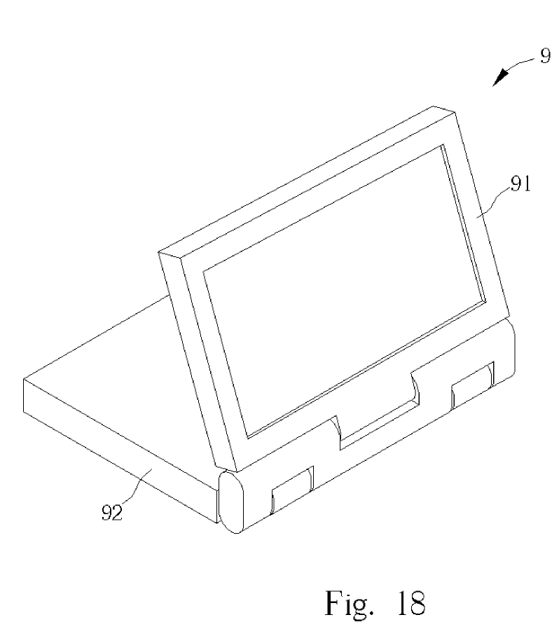

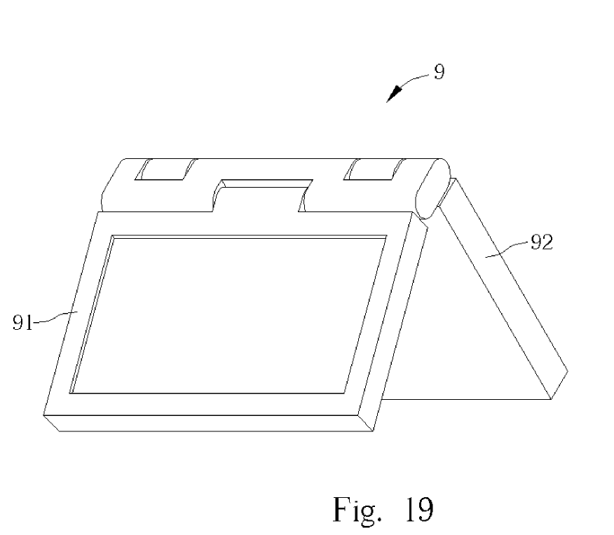

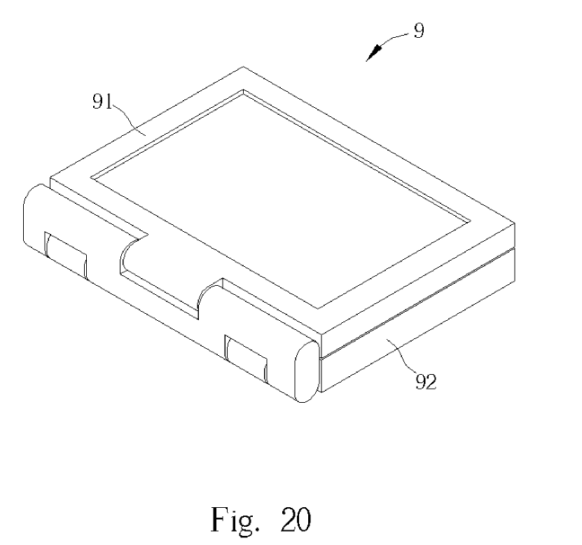

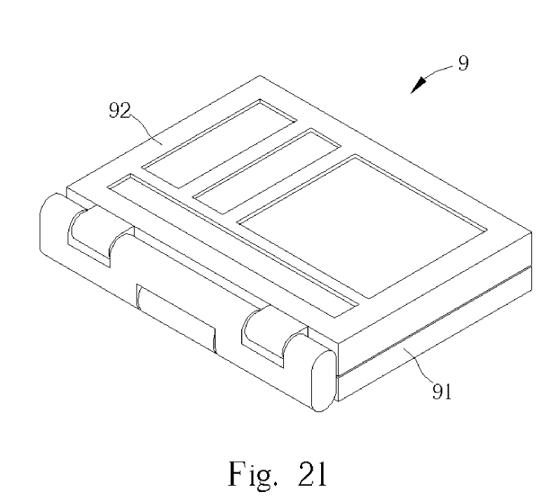

Therefore, if a folder-style electronic device uses the double hinge structure according to the present invention, the screen 91 can be rotated to a position directly on top of the input area 92 or directly underneath the input area 92. This means the double hinge structure 8 provides a 360-degree rotating function. This is in contrast to all folder-style electronic products based on the prior art, which do not provide a 360-degree rotating function because their screens can at most be rotated 180 degrees. (Which makes the angles between the input areas and the corresponding screens at most 180 degrees—please refer to FIG. 5 and FIG. 6). Please refer to FIG. 18, FIG. 19, FIG. 20 and FIG. 21. FIG. 18 to FIG. 21 are three-dimensional diagrams of a folder-style electronic device 9 that uses a double hinge structure viewed from a first, a second, a third, and a fourth view, respectively. The 360-degree rotating function of the double hinge structure allows a folder-style electronic device 9 to have a more changeable view angle. Any side of the folder-style electronic device 9 can be used as a holder. When the screen 91 is rotated to the position directly underneath the input area 92, users can still input instructions through the input area 92 and the screen 91 can still display information. In this working position, the folder-style electronic device 9 saves the most space.

Those skilled in the art will readily observe that numerous modifications and alterations of the device may be made while retaining the teachings of the invention. Accordingly, the above disclosure should be construed as limited only by the metes and bounds of the appended claims.

What is claimed is:

1. A folder-style electronic device comprising:
a first unit;
a second unit; and
a double hinge structure utilized for connecting the first unit and the second unit and making the first unit rotate to a first position directly on top of the second unit or to a second position directly underneath the second unit.

2. The folder-style electronic device of claim 1, wherein the first unit is a screen utilized for displaying.

3. The folder-style electronic device of claim 1, wherein the second unit is an input area utilized for inputting instructions.

4. The folder-style electronic device of claim 1, wherein the first unit comprises at least a fastener location utilized for connecting the double hinge structure.

5. The folder-style electronic device of claim 4, wherein the second unit comprises at least a fastener location utilized for connecting the double hinge structure.

6. The folder-style electronic device of claim 5, wherein the double hinge structure comprises:
a plurality of bolts;
at least a plate installed and rotatable on the plurality of bolts; and
a plurality of fasteners installed and rotatable on the plurality of bolts.

7. The double hinge structure of claim 6, wherein each of the plurality of fasteners is respectively attached to a corresponding fastener location.

8. A double hinge structure comprising:
a plurality of bolts;
at least a plate installed and rotatable on the plurality of bolts; and
a plurality of fasteners installed and rotatable on the plurality of bolts.

9. The double hinge structure of claim 8, wherein the double hinge structure is utilized in a folder-style electronic device.
